(19) United States
(12) Patent Application Publication
(10) Pub. No.: US 2018/0323347 A1
(43) Pub. Date: Nov. 8, 2018

(54) THIN FILM TRANSISTOR, DISPLAY SUBSTRATE, METHODS FOR MANUFACTURING THE SAME AND DISPLAY DEVICE

(71) Applicant: BOE TECHNOLOGY GROUP CO., LTD., Beijing (CN)

(72) Inventor: Wei Liu, Beijing (CN)

(21) Appl. No.: 15/871,525

(22) Filed: Jan. 15, 2018

(30) Foreign Application Priority Data
May 8, 2017 (CN) 201710317056.3

(51) Int. Cl. H01L 33/44; H01L 33/36; H01L 27/15; H01L 33/00

(52) U.S. Cl. CPC H01L 33/44; H01L 33/0095; H01L 27/156; H01L 33/36

(57) ABSTRACT

A thin film transistor, a display substrate, manufacturing methods thereof, and a display device are provided. The manufacturing method for the thin film transistor includes: forming a light-shielding metal pattern and a source-drain metal layer pattern on a base substrate; forming a buffer layer including first and second via-holes; forming a source electrode connected with the light-shielding metal pattern via the first via-hole, a drain electrode connected with the source-drain metal layer pattern via the second via-hole, and an active layer, an orthographic projection of the light-shielding metal pattern on the substrate completely covering that of the active layer on the substrate and at least partially covering those of the source and drain electrodes on the substrate; and forming a gate insulation layer and a gate electrode, orthographic projections of the gate insulation layer and the gate electrode on the substrate being identical.

### CROSS-REFERENCE TO RELATED APPLICATION

This application claims a priority to Chinese Patent Application No. 201710317056.3 filed on May 8, 2017, the disclosure of which is incorporated in its entirety by reference herein.

### TECHNICAL FIELD

The present disclosure relates to a thin film transistor, a display substrate, a method for manufacturing the thin film transistor, a method for manufacturing the display substrate, and a display device.

### BACKGROUND

A top-gate oxide thin film transistor (TFT) is considered as a primary technical choice for an active matrix organic light-emitting diode (AMOLED) display having a large size and a high resolution, due to a low parasitic capacitance and good electrical characteristics thereof. The top-gate oxide thin film transistor TFT is usually manufactured by using a self-aligned technical process in a coplanar structure. In the top-gate oxide thin film transistor TFT with the self-aligned coplanar structure, an oxide active layer is under a source-drain metal layer and a gate metal layer and is adjacent to a base substrate, and thus the oxide active layer is easily illuminated by an external light source or ambient light. Due to poor stability of the oxide active layer when being illuminated, the top-gate oxide TFT having the self-aligned coplanar structure is usually provided with a metal pattern under the oxide active layer for shielding light.

### SUMMARY

The present disclosure provides a thin film transistor, a display substrate, a method for manufacturing the thin film transistor, a method for manufacturing the display substrate, and a display device including the display substrate.

In a first aspect, a method for manufacturing a thin film transistor is provided in the present disclosure and includes: forming a light-shielding metal pattern and a source-drain metal layer pattern on a base substrate; forming a buffer layer covering the light-shielding metal pattern and the source-drain metal layer pattern, and patterning the buffer layer to form a first via-hole exposing a part of the light-shielding metal pattern and a second via-hole exposing a part of the source-drain metal layer pattern; forming a semiconductor layer pattern on the buffer layer, wherein the semiconductor layer pattern includes a source electrode region, a drain electrode region, and an active layer between the source electrode region and the drain electrode region, an orthographic projection of the light-shielding metal pattern on the base substrate completely covers an orthographic projection of the active layer on the base substrate and at least covers a part of an orthographic projection of the source electrode region on the base substrate and a part of an orthographic projection of the drain electrode region on the base substrate, the source electrode region is electrically connected with the light-shielding metal pattern via the first via-hole, and the drain electrode region is electrically connected with the source-drain metal layer pattern via the second via-hole; and forming a gate insulation layer pattern and a gate electrode on the semiconductor layer pattern, wherein an orthographic projection of the gate insulation layer pattern on the base substrate coincides with an orthographic projection of the gate electrode on the base substrate.

Optionally, the method for manufacturing a thin film transistor further includes: performing conductive treatment on the source electrode region and the drain electrode region by implanting metal ions or performing plasma treatment and by taking the gate electrode as a mask, so as to form a source electrode and a drain electrode of the thin film transistor, respectively.

Optionally, the forming the light-shielding metal pattern and the source-drain metal layer pattern on the base substrate includes: forming the light-shielding metal pattern and the source-drain metal layer pattern on the base substrate simultaneously in a first patterning process; and the forming the gate insulation layer pattern and the gate electrode includes: forming the gate insulation layer pattern and the gate electrode simultaneously in a second patterning process.

Optionally, the forming the semiconductor layer pattern on the buffer layer includes forming the semiconductor layer pattern on the buffer layer by using a metal oxide semiconductor material.

Optionally, the forming the light-shielding metal pattern and the source-drain metal layer pattern on the base substrate includes: depositing a metal layer on the base substrate by using a sputtering process or a thermal-evaporation process; and patterning the metal layer to simultaneously form the light-shielding metal pattern and the source-drain metal layer pattern, wherein the base substrate is a glass substrate or a quartz substrate, and the metal layer is formed of any one of Cu, Al, Ag, Mo, Cr, Nd, Ni, Mn, Ti, Ta, W, or any combination of Cu, Al, Ag, Mo, Cr, Nd, Ni, Mn, Ti, Ta, and W.

In a second aspect, a thin film transistor is provided in the present disclosure, and include: a light-shielding metal pattern and a source-drain metal layer pattern on a base substrate and in an identical layer; a buffer layer covering the light-shielding metal pattern and the source-drain metal layer pattern, wherein the buffer layer includes a first via-hole corresponding to the light-shielding metal pattern and a second via-hole corresponding to the source-drain metal layer pattern;

a source electrode, a drain electrode and an active layer on the buffer layer, wherein an orthographic projection of the light-shielding metal pattern on the base substrate completely covers an orthographic projection of the active layer on the base substrate and at least covers a part of an orthographic projection of the source electrode on the base substrate and a part of an orthographic projection of the drain electrode on the base substrate, and the source electrode is electrically connected with the light-shielding metal pattern via the first via-hole, and the drain electrode is electrically connected with the source-drain metal layer pattern via the second via-hole; a gate insulation layer pattern on the active layer; and a gate electrode on the gate insulation layer pattern, wherein an orthographic projection of the gate electrode on the base substrate coincides with an orthographic projection of the gate insulation layer pattern on the base substrate.

Optionally, an orthographic projection of the active layer on the base substrate coincides with the orthographic projection of the gate insulation layer pattern on the base substrate, and contents of metal ions in the source electrode and the drain electrode are higher than contents of metal ions in the active layer.

In a third aspect, a method for manufacturing a display substrate is provided in the present disclosure and includes manufacturing a thin film transistor on a base substrate by using the method according to the first aspect.

Optionally, after manufacturing the thin film transistor, the method further includes: forming a passivation layer covering the gate electrode, the source electrode region, the drain electrode region and the buffer layer; and patterning the passivation layer to form a third via-hole exposing a part of the drain electrode region of the thin film transistor; and forming a pattern of a pixel electrode on the passivation layer, wherein the pixel electrode is electrically connected with the drain electrode region via the third via-hole.

Optionally, the method for manufacturing a display substrate further includes: performing conductive treatment on the source electrode region and the drain electrode region by implanting metal ions or performing plasma treatment and taking the gate electrode as a mask, so as to form a source electrode and a drain electrode of the thin film transistor, respectively.

In a fourth aspect, a display substrate is provided in the present disclosure and includes: the thin film transistor on the base substrate according to the second aspect.

Optionally, an orthographic projection of the active layer on the base substrate coincides with an orthographic projection of the gate insulation layer pattern on the base substrate, and contents of metal ions in the source electrode and the drain electrode are higher than contents of metal ions in the active layer.

Optionally, the display substrate further includes: a passivation layer covering the thin film transistor; and a pixel electrode electrically connected with the drain electrode of the thin film transistor via a third via-hole penetrating through the passivation layer.

In a fifth aspect, a display device is provided in the present disclosure, and includes a display substrate according to the above fourth aspect.

### BRIEF DESCRIPTION OF THE DRAWINGS

FIG. 1A is a structural schematic diagram of a thin film transistor according to some embodiments of the present disclosure;

FIG. 1B is a structural schematic diagram of another example of the thin film transistor according to some embodiments of the present disclosure;

FIG. 2A is a structural schematic diagram of a display substrate according to some embodiments of the present disclosure;

FIG. 2B is a structural schematic diagram of another example of the display substrate according to some embodiments of the present disclosure;

FIG. 3 is a flowchart of a method for manufacturing a thin film transistor according to some embodiments of the present disclosure;

FIG. 4 is a flowchart of a method for manufacturing a display substrate according to some embodiments of the present disclosure;

FIGS. 5 to 11 are schematic flowcharts of the method for manufacturing a display substrate according to some embodiments of the present disclosure; and

FIG. 12 is a schematic diagram of a planar structure of the display substrate according to some embodiments of the present disclosure.

### DETAILED DESCRIPTION

To make technical problems, technical solutions and advantages of embodiments of the present disclosure clearer, the embodiments will be described in detail in conjunction with drawings hereinafter.

The embodiments of the present disclosure provide a thin film transistor, a display substrate, methods for manufacturing the thin film transistor and the display substrate, and a display device including the thin film transistor and the display substrate.

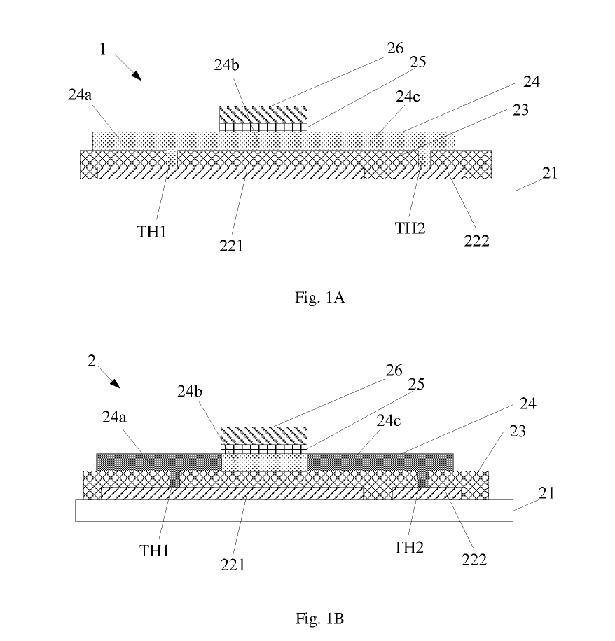

FIG. 1A is a structural schematic diagram of a thin film transistor 1 according to some embodiments of the present disclosure. As shown in FIG. 1A, the thin film transistor 1 includes a light-shielding metal pattern 221 and a source-drain metal layer pattern 222 on a base substrate 21; a buffer layer 23 covering the light-shielding metal pattern 221 and the source-drain metal layer pattern 222, wherein the buffer layer 23 includes a first via-hole TH1 corresponding to the light-shielding metal pattern 221 and a second via-hole TH2 corresponding to the source-drain metal layer pattern; a semiconductor layer pattern 24 on the buffer layer 23 and including a source electrode region 24a, a drain electrode region 24c and an active layer 24b; a gate insulation layer pattern 25 on the active layer 24b; and a gate electrode 26 on the gate insulation layer pattern 25. An orthographic projection of the light-shielding metal pattern 221 on the base substrate 21 completely covers an orthographic projection of the active layer 24b on the base substrate 21, and at least covers a part of an orthographic projection of the source electrode region 24a on the base substrate 21 and a part of an orthographic projection of the drain electrode region 24c on the base substrate 21. The source electrode region 24a is electrically connected with the light-shielding metal pattern 221 via the first via-hole TH1, and the drain electrode region 24c is electrically connected with the source-drain metal layer pattern 222 via the second via-hole TH2. An orthographic projection of the gate electrode 26 on the base substrate 21 coincides with an orthographic projection of the gate insulation layer pattern 25 on the base substrate 21. It should be noted that “electrically connected” mentioned in the present disclosure may be “directly connected” or “indirectly connected”.

FIG. 1B is a structural schematic diagram of another example of a thin film transistor 2 according to some embodiments of the present disclosure. A structure of the thin film transistor 2 is substantially identical to a structure of the thin film transistor 1 as shown in FIG. 1A, and thus the same reference numerals are used to denote the same features in FIGS. 1A and 1B. A difference between the thin film transistor 2 as shown in FIG. 1B and the thin film transistor 1 as shown in FIG. 1A is that conductive treatment is performed on the source electrode region 24a and the drain electrode region 24c of the thin film transistor 2. That is, the source electrode region 24a and the drain electrode region 24c of the thin film transistor 2 are subjected to ion-implantation or plasma-treatment, so as to enhance the conductivity of the source electrode region 24a and the drain electrode region 24c.

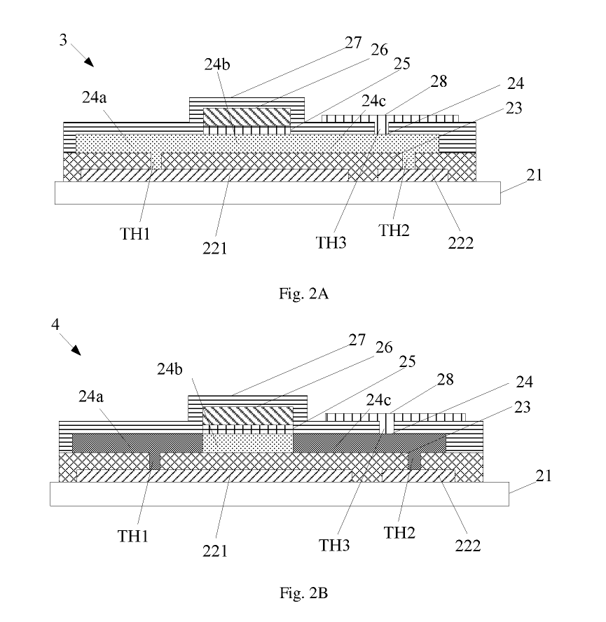

The embodiments of the present disclosure further provide a display substrate. FIG. 2A is a structural schematic diagram of a display substrate 3 according to some embodiments of the present disclosure. As shown in FIG. 2A, the display substrate 3 includes the above-mentioned thin film transistor 1 on the base substrate 21; a passivation layer 27 covering the thin film transistor 1, and a pixel electrode 28 electrically connected with the drain electrode region 24c of the thin film transistor 1 via a third via-hole TH3 penetrating through the passivation layer 27.

FIG. 2B is a structural schematic diagram of a display substrate 4 according to some embodiments of the present disclosure. As shown in FIG. 2B, the display substrate 4 includes the above-mentioned thin film transistor 2 on the base substrate 21; a passivation layer 27 covering the thin film transistor 2; and the pixel electrode 28 electrically connected with the drain electrode region 24c of the thin film transistor 2 via the third via-hole TH3 penetrating through the passivation layer 27.

In the display substrate according to the embodiments of the present disclosure, because the first via-hole connecting the source electrode region with the light-shielding metal pattern and the second via-hole connecting the drain electrode region with the source-drain metal layer pattern only penetrate through the buffer layer, depths of the first via-hole and the second via-hole are small, which reduces a difficulty of a process for forming the via-holes and eliminates defects generated in the process, thereby ensuring a product yield of the thin film transistor. Moreover, in the embodiments of the present disclosure, not only the semiconductor layer pattern subjected to the conductive treatment are used as the source and drain electrodes, but also a metal is used to manufacture the source-drain metal layer pattern, which may ensure the conductivity of the source drain electrodes and avoid IR (Internal Resistance) Drop phenomenon, thereby improving a display effect of a display device.

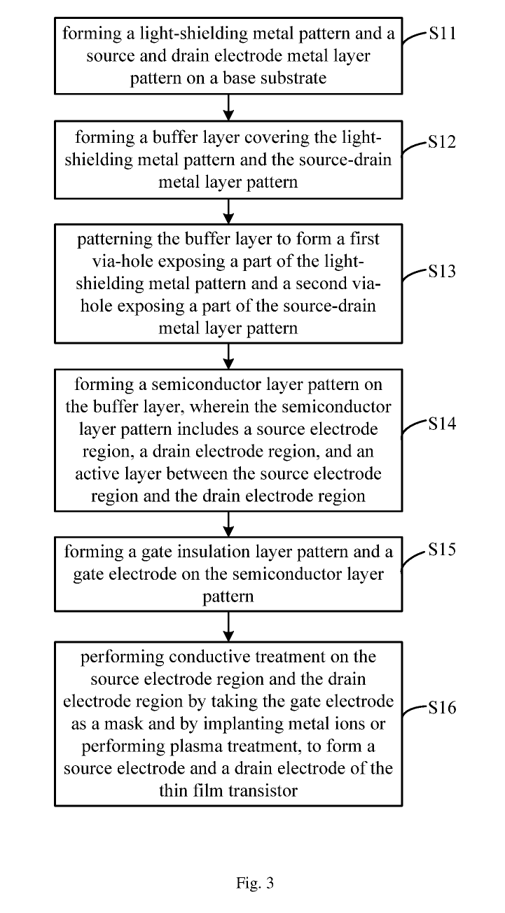

Some embodiments of the present disclosure further provide a method for manufacturing the above-mentioned thin film transistor. As shown in FIG. 3, the method for manufacturing the thin film transistor includes steps S11 to S15.

Step S11: forming a light-shielding metal pattern and a source-drain metal layer pattern on a base substrate.

Step S12: forming a buffer layer covering the light-shielding metal pattern and the source-drain metal layer pattern.

Step S13: patterning the buffer layer to form a first via-hole exposing a part of the light-shielding metal pattern and a second via-hole exposing a part of the source -drain metal layer pattern.

Step S14: forming a semiconductor layer pattern on the buffer layer, wherein the semiconductor layer pattern includes a source electrode region, a drain electrode region, and an active layer between the source electrode region and the drain electrode region. An orthographic projection of the light-shielding metal pattern on the base substrate completely covers an orthographic projection of the active layer on the base substrate, and at least covers a part of an orthographic projection of the source electrode region on the base substrate and a part of an orthographic projection of the drain electrode region on the base substrate. The source electrode region is electrically connected with the light-shielding metal pattern via the first via-hole, and the drain electrode region is electrically connected with the source-drain metal layer pattern via the second via-hole.

Step S15: forming a gate insulation layer pattern and a gate electrode on the semiconductor layer pattern, wherein an orthographic projection of the gate insulation layer pattern on the base substrate coincides with an orthographic projection of the gate electrode on the base substrate.

In the embodiments of the present disclosure, because the first via-hole connecting the source electrode region with the light-shielding metal pattern and the second via-hole connecting the drain electrode region with the source-drain metal layer pattern only penetrate through the buffer layer, depths of the first via-hole and the second via-hole are small, which reduces the difficulty of process for forming the via-holes and eliminates the defects generated in the process, thereby ensuring the product yield of the thin film transistor. Moreover, in the embodiments, not only the semiconductor layer pattern subjected to the conductive treatment is used as the source and drain electrodes, but also a metal is used to manufacture the source-drain metal layer pattern, which may ensure the conductivity of the source and drain electrodes and avoid the IR (Internal Resistance) Drop phenomenon, thereby improving the display effect of the display device.

Optionally, the method for manufacturing the thin film transistor further includes step S16.

Step S16: performing conductive treatment on the source electrode region and the drain electrode region by taking the gate electrode as a mask and by implanting metal ions or performing plasma treatment, so as to form a source electrode and a drain electrode of the thin film transistor, respectively.

The step S11 of forming the light-shielding metal pattern and the source-drain metal layer pattern on the base substrate further includes: forming the light-shielding metal pattern and the source-drain metal layer pattern on the base substrate simultaneously in a single patterning process.

In such a manner, an additional patterning process is not required to manufacture the light-shielding metal pattern, which may reduce the number of patterning processes for manufacturing the thin film transistor and a manufacturing cost of the thin film transistor may be lowered.

The step S15 of forming the gate insulation layer pattern and the gate electrode further includes: forming the gate insulation layer pattern and the gate electrode simultaneously in a single patterning process.

In such a manner, the number of patterning processes for manufacturing the thin film transistor is reduced, and the manufacturing cost of the thin film transistor may be lowered.

Further, the semiconductor layer pattern is made of metal oxide, such as IGZO (indium gallium zinc oxide) or ITZO (indium tin zinc oxide). Optionally, the semiconductor layer pattern may also be made of other semiconductor materials, such as amorphous silicon and polycrystalline silicon, which will not be listed herein one by one.

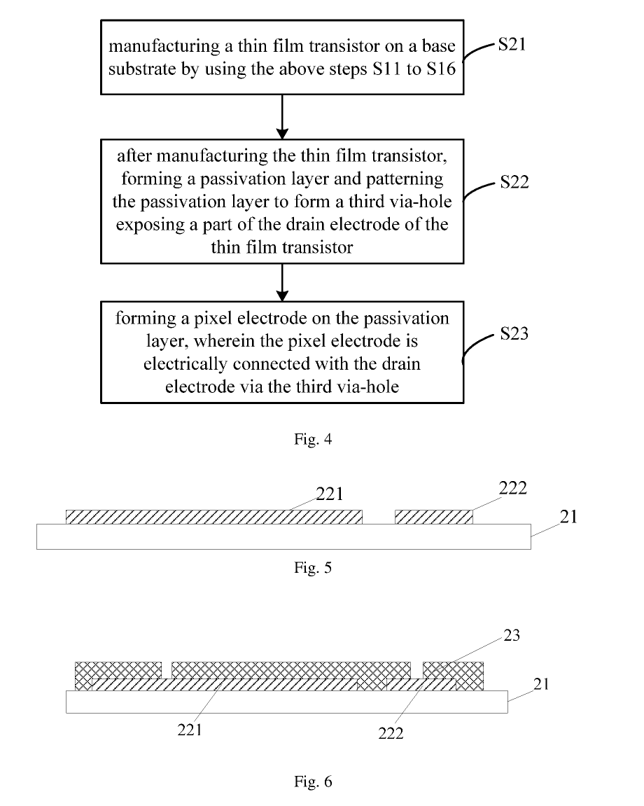

Some embodiments of the present disclosure further provide a method for manufacturing a display substrate. As shown in FIG. 4, the method for manufacturing the display substrate includes steps S21 to S23.

Step S21: manufacturing a thin film transistor on a base substrate by using the above steps S11 to S16.

Step S22: after manufacturing the thin film transistor, forming a passivation layer and patterning the passivation layer to form a third via-hole exposing a part of the drain electrode of the thin film transistor.

Step S23: forming a pattern of a pixel electrode on the passivation layer, wherein the pixel electrode is electrically connected with the drain electrode via the third via-hole.

The method for manufacturing the display substrate according to the embodiments of the present disclosure will be described in detail in conjunction with FIGS. 5 to 11 hereinafter. Specifically, the method for manufacturing the display substrate according to the embodiments of the present disclosure includes the following steps S31 to S37.

Step S31: as shown in FIG. 5, providing a base substrate 21, and forming a light-shielding metal pattern 221 and a source-drain metal layer pattern 222 on the base substrate 21.

The base substrate 21 may be a glass substrate or a quartz substrate. A metal layer may be deposited on the base substrate 21 by using a sputtering process or a thermal-evaporation process. The metal layer may be patterned to form the light-shielding metal pattern 221 and the source-drain metal layer pattern 222. The metal layer may be a metal such as Cu, Al, Ag, Mo, Cr, Nd, Ni, Mn, Ti, Ta, W, or an alloy of any combination of these metals. Any conductive metal film capable of shielding light may be used to manufacture the light-shielding metal pattern 221 and the source-drain metal layer pattern 222. The light-shielding metal pattern 221 is configured to prevent light from illuminating the active layer of the thin film transistor, and the source-drain metal layer pattern 222 may be used as a data line.

Step S32: as show in FIG. 6, forming a buffer layer 23. The buffer layer 23 includes a first via-hole TH1 exposing a part of the light-shielding metal pattern 221 and a second via-hole TH2 exposing a part of the source-drain metal layer pattern 222.

The buffer layer 23 may be made of SiOx, or SiNx, or may be formed of a composite film layer made of SiOx and SiNx, wherein x represents a positive integer.

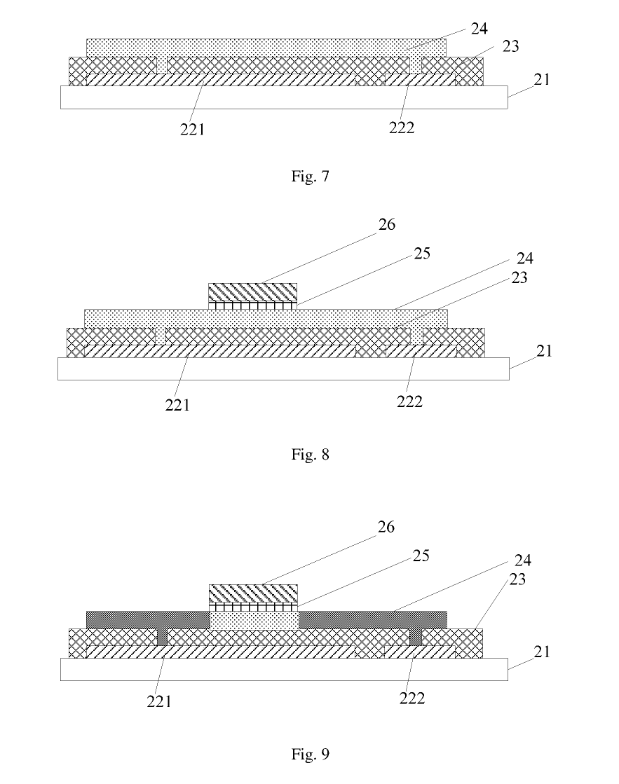

Step S33: as shown in FIG. 7, depositing a layer of semiconductor material on the buffer layer 23, and patterning the layer of semiconductor material to form the semiconductor layer pattern 24.

The layer of semiconductor material may be made of metal oxide semiconductor such as IGZO or ITZO. The semiconductor layer pattern 24 includes the source electrode region 24a, the drain electrode region 24c and the active layer 24b between the source electrode region 24a and the drain electrode region 24c. The orthographic projection of the light-shielding metal pattern 221 on the base substrate 21 completely covers the orthographic projection of the active layer 24b on the base substrate 21, and at least covers a part of the orthographic projection of the source electrode region 24a on the base substrate 21 and a part of the orthographic projection of the drain electrode region 24c on the base substrate 21. The source electrode region 24a is electrically connected with the light-shielding metal pattern 221 via the first via-hole TH1, and the drain electrode region 24c is electrically connected with the source-drain metal layer pattern 222 via the second via-hole TH2.

Step S34: as shown in FIG. 8, forming the gate insulation layer pattern 25 and the gate electrode 26 on the semiconductor layer pattern 24.

The gate insulation layer pattern 25 and the gate electrode 26 may be formed in two respective patterning processes, or may be formed simultaneously in a single patterning process. The orthographic projection of the gate electrode 26 on the base substrate 21 coincides with the orthographic projection of the gate insulation layer pattern 25 on the base substrate 21.

Step S35: as shown in FIG. 9, performing the conductive treatment on the semiconductor layer pattern 24 by taking the gate electrode 26 as a mask, so as to improve the conductivity of the source electrode region and the drain electrode region and form the source electrode and the drain electrode of the thin film transistor.

Specifically, the conductive treatment may be performed on the semiconductor layer pattern 24 by implanting metal ions or performing the plasma treatment.

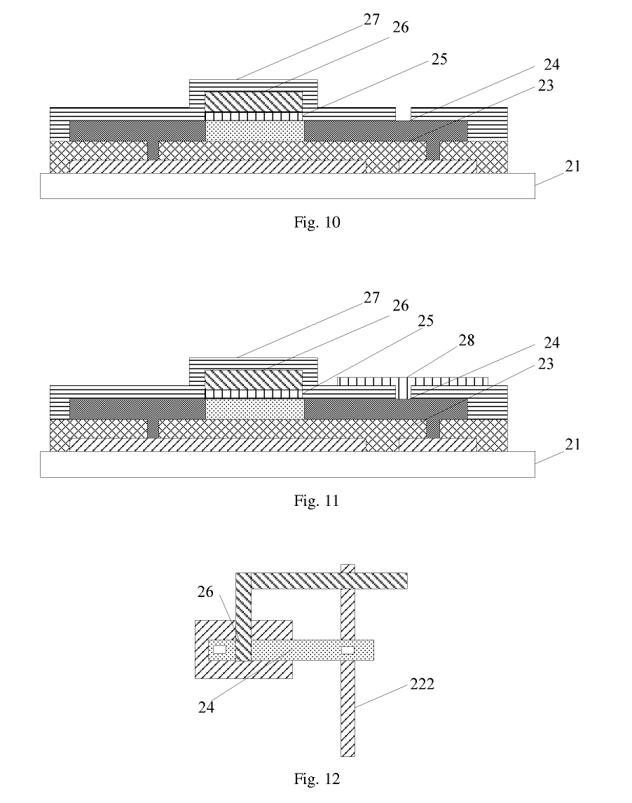

Step S36: as shown in FIG. 10, forming the passivation layer 27.

Specifically, a layer of passivation material may be deposited on the base substrate 21 after the step S34 or the step S35 is performed, and the layer of passivation material is patterned to form the passivation layer 27. The passivation layer 27 includes a third via-hole TH3 exposing a part of the drain electrode of the thin film transistor.

Step S37: as shown in FIG. 11, forming the pixel electrode 28.

A layer of transparent conductive material may be deposited on the base substrate 21 after the step S36 is performed, and the layer of transparent conductive material is patterned to form the pixel electrode 28. The pixel electrode 28 is electrically connected with the drain electrode 24c of the thin film transistor via the third via-hole TH3 penetrating through the passivation layer 27.

The display substrate according to the embodiments may be manufactured through the above steps S31 to S37. FIG. 12 is a planar structural schematic diagram of the display substrate according to the embodiments of the present disclosure.

If the display substrate is an OLED display substrate, an anode, a cathode and a light-emitting layer of an OLED device are also required to be manufactured after the display substrate is manufactured though the above steps. A light-emitting function may be achieved by connecting the anode with the pixel electrode 28.

It may be seen that, as compared with relevant manufacturing processes of a display substrate, the number of patterning processes for manufacturing the display substrate of the embodiments of the present disclosure may be greatly reduced, and the production cost of the display substrate may be lowered. Furthermore, because the first via-hole connecting the source electrode region with the light-shielding metal pattern and the second via-hole connecting the drain electrode region with the source-drain metal layer pattern only penetrate through the buffer layer, depths of the first via-hole and the second via-hole are small and the same. Therefore, the difficulty of the process for forming the via-holes may be reduced and the defects generated in the process may be eliminated, thereby ensuring the product yield of the thin film transistor. Moreover, in the embodiments of the present disclosure, not only the semiconductor layer pattern subjected to the conductive treatment is used as the source and drain electrodes, but a metal material used to manufacture the light-shielding metal pattern is used to form the source-drain metal layer pattern, which may ensure the conductivity of the source and drain electrodes and avoid IR Drop, thereby improving the display effect of the display device.

Some embodiments of the present disclosure further provide a display device, including the display substrate as described above. The display device may be any product or component having a display function such as a television, a display, a digital photo frame, a cell phone, or a tablet computer. The display device further includes a flexible circuit board, a printed circuit board and a back plate.

In the embodiments of the present disclosure, numbering of the steps does not necessarily define a sequence of the steps. Variation of the sequence of the steps also falls into the protection scope of the present disclosure for one of ordinary skills in the art on the premise of paying not creative work.

Unless otherwise defined, technical terms or scientific terms used in the present disclosure should be interpreted according to common meanings thereof as commonly understood by those of ordinary skills in the art. Such terms as “first”, “second” and the like used in the present disclosure do not represent any order, quantity or importance, but are merely used to distinguish different components. Such terms as “including”, “includes”, “include”, “comprise”, “comprises” or “comprising” and the like mean that an element or an article preceding the term contains elements or items and equivalents thereof behind the term, but does not exclude other elements or items. Such terms as “connect”, “connected” or “connecting” and the like are not limited to physical or mechanical connections, but may include electrical connections, whether direct connection or indirect connection. Such terms as “on”, “under”, “left”, “right” and the like are only used to represent a relative position relationship, and when an absolute position of a described object is changed, the relative position relationship thereof may also be changed accordingly.

It may be understood that when an element such as a layer, a film, a region or a substrate is referred to as being “on” or “under” another element, the element may be “directly” “on” or “ under ” the another element, or there may exist an intervening element.

The above embodiments are merely optional embodiments of the present disclosure. It should be noted that numerous improvements and modifications may be made by those skilled in the art without departing from the principle of the present disclosure, and these improvements and modifications shall also fall within the scope of the present disclosure.

What is claimed is:

1. A method for manufacturing a thin film transistor, comprising:
forming a light-shielding metal pattern and a source-drain metal layer pattern on a base substrate;
forming a buffer layer covering the light-shielding metal pattern and the source-drain metal layer pattern, and patterning the buffer layer to form a first via-hole exposing a part of the light-shielding metal pattern and a second via-hole exposing a part of the source-drain metal layer pattern;
forming a semiconductor layer pattern on the buffer layer, wherein the semiconductor layer pattern comprises a source electrode region, a drain electrode region, and an active layer between the source electrode region and the drain electrode region, an orthographic projection of the light-shielding metal pattern on the base substrate completely covers an orthographic projection of the active layer on the base substrate and at least covers a part of an orthographic projection of the source electrode region on the base substrate and a part of an orthographic projection of the drain electrode region on the base substrate, the source electrode region is electrically connected with the light-shielding metal pattern via the first via-hole, and the drain electrode region is electrically connected with the source-drain metal layer pattern via the second via-hole; and
forming a gate insulation layer pattern and a gate electrode on the semiconductor layer pattern, wherein an orthographic projection of the gate insulation layer pattern on the base substrate coincides with an orthographic projection of the gate electrode on the base substrate.

2. The method for manufacturing a thin film transistor according to claim 1, further comprising:
performing conductive treatment on the source electrode region and the drain electrode region by implanting metal ions or performing plasma treatment and by taking the gate electrode as a mask, so as to form a source electrode and a drain electrode of the thin film transistor, respectively.

3. The method for manufacturing a thin film transistor according to claim 1, wherein forming the light-shielding metal pattern and the source-drain metal layer pattern on the base substrate comprises:
forming the light-shielding metal pattern and the source-drain metal layer pattern on the base substrate simultaneously in a first patterning process, and wherein forming the gate insulation layer pattern and the gate electrode comprises:
forming the gate insulation layer pattern and the gate electrode simultaneously in a second patterning process.

4. The method for manufacturing a thin film transistor according to claim 1, wherein forming the semiconductor layer pattern on the buffer layer comprises forming the semiconductor layer pattern on the buffer layer by using a metal oxide semiconductor material.

5. The method for manufacturing a thin film transistor according to claim 1, wherein forming the light-shielding metal pattern and the source-drain metal layer pattern on the base substrate comprises:
depositing a metal layer on the base substrate by using a sputtering process or a thermal-evaporation process; and
patterning the metal layer to simultaneously form the light-shielding metal pattern and the source-drain metal layer pattern,
wherein the base substrate is a glass substrate or a quartz substrate, and the metal layer is formed of any one of Cu, Al, Ag, Mo, Cr, Nd, Ni, Mn, Ti, Ta, W, or any combination of Cu, Al, Ag, Mo, Cr, Nd, Ni, Mn, Ti, Ta, and W.

6. A thin film transistor, comprising:
a light-shielding metal pattern and a source-drain metal layer pattern on a base substrate and in an identical layer;
a buffer layer covering the light-shielding metal pattern and the source-drain metal layer pattern, wherein the buffer layer comprises a first via-hole corresponding to the light-shielding metal pattern and a second via-hole corresponding to the source-drain metal layer pattern;
a source electrode, a drain electrode and an active layer on the buffer layer, wherein an orthographic projection of the light-shielding metal pattern on the base substrate completely covers an orthographic projection of the active layer on the base substrate and at least covers a part of an orthographic projection of the source electrode on the base substrate and a part of an orthographic projection of the drain electrode on the base substrate, and the source electrode is electrically connected with the light-shielding metal pattern via the first via-hole, and the drain electrode is electrically connected with the source-drain metal layer pattern via the second via-hole;
a gate insulation layer pattern on the active layer; and
a gate electrode on the gate insulation layer pattern, wherein an orthographic projection of the gate electrode on the base substrate coincides with an orthographic projection of the gate insulation layer pattern on the base substrate.

7. The thin film transistor according to claim 6, wherein an orthographic projection of the active layer on the base substrate coincides with the orthographic projection of the gate insulation layer pattern on the base substrate, and contents of metal ions in the source electrode and the drain electrode are higher than contents of metal ions in the active layer.

8. A method for manufacturing a display substrate, comprising:
manufacturing a thin film transistor on a base substrate by using the method according to claim 1.

9. The method for manufacturing a display substrate according to claim 8, wherein after manufacturing the thin film transistor, the method further comprises:
forming a passivation layer covering the gate electrode, the source electrode region, the drain electrode region and the buffer layer, and patterning the passivation layer to form a third via-hole exposing a part of the drain electrode region of the thin film transistor; and
forming a pattern of a pixel electrode on the passivation layer, wherein the pixel electrode is electrically connected with the drain electrode region via the third via-hole.

10. The method for manufacturing a display substrate according to claim 8, further comprising:
performing conductive treatment on the source electrode region and the drain electrode region by implanting metal ions or performing plasma treatment and by taking the gate electrode as a mask, so as to form a source electrode and a drain electrode of the thin film transistor, respectively.

11. A display substrate, comprising:
the thin film transistor on the base substrate according to claim 6.

12. The display substrate according to claim 11, wherein an orthographic projection of the active layer on the base substrate coincides with an orthographic projection of the gate insulation layer pattern on the base substrate, and contents of metal ions in the source electrode and the drain electrode are higher than contents of metal ions in the active layer.

13. The display substrate according to claim 11, further comprising:
a passivation layer covering the thin film transistor; and
a pixel electrode electrically connected with the drain electrode of the thin film transistor via a third via-hole penetrating through the passivation layer.

14. A display device, comprising:
a display substrate according to claim 11.
